(19) United States
(12) Patent Application Publication
(10) Pub. No.: US 2025/0011226 A1
(43) Pub. Date: Jan. 9, 2025

(54) ION BARRIER COATING FOR LEAD GLASS MICROCHANNEL PLATES AND OTHER APPLICATIONS

(71) Applicant: Incom, Inc., Charlton, MA (US)

(72) Inventors: Anil U. Mane, Naperville, IL (US); Jeffrey W. Elam, Elmhurst, IL (US); Michael J. Minot, Andover, MA (US); Stephen M. Clarke, Worcester, MA (US); Cole J. Hamel, Worcester, MA (US); Derrick O. Mensah, East Brookfield, MA (US); Mark A. Popecki, Durham, NH (US); Melvin Aviles, Southbridge, MA (US); Michael E. Stochaj, Shrewsbury, MA (US); Stefan Cwik, Braintree, MA (US)

(21) Appl. No.: 18/763,257

(22) Filed: Jul. 3, 2024

Related U.S. Application Data
(60) Provisional application No. 63/525,389, filed on Jul. 7, 2023.

(51) Int. Cl. C03C 17/34; H01L 31/0392; H01L 31/18

(52) U.S. Cl. CPC C03C 17/34; H01L 31/0392; H01L 31/18; C03C 2217/229; C03C 2218/152; C03C 2218/32

(57) ABSTRACT

A functionalized glass device, such as a microchannel plate, includes a glass substrate having a chemistry including an ionic species that may diffuse toward a surface, and a functional layer supported by the glass substrate and having a functional characteristic that may be undesirably altered by introduction of the ionic species during operation of the device. An ion barrier layer is disposed between the surface of the glass substrate and the functional layer, the ion barrier layer being substantially of a metal oxide material effective to limit the diffusion of the ionic species into the functional layer.

### CROSS REFERENCE TO RELATED APPLICATIONS

This application claims priority under 35 USC 119 (e) to U.S. Provisional Application No. 63/525,389 filed Jul. 7, 2023 (referred to herein as the Provisional Application), the complete contents of which are incorporated by reference herein in their entirety.

### STATEMENT OF GOVERNMENT RIGHTS

The invention was made with Government support under the following contracts:
1. Contract No. DE-AC02-06CH11357 by the U. S. Department Of Energy
2. SPP Agreement No. A22097 between UChicago Argonne, LLC (as operator of Argonne National Laboratory) and Incom, Inc.

The Government has certain rights in the invention.

### BACKGROUND

The invention relates to the field of devices employing coated glass substrates such as microchannel plates (MCPs).

### SUMMARY

A functionalized glass device, such as a microchannel plate, includes a glass substrate having a chemistry including an ionic species that may diffuse toward a surface, and a functional layer supported by the glass substrate and having a functional characteristic that may be undesirably altered by introduction of the ionic species during operation of the device. An ion barrier layer is disposed between the surface of the glass substrate and the functional layer, the ion barrier layer being substantially of a metal oxide material effective to limit the diffusion of the ionic species into the functional layer, thereby reducing or eliminating an adverse effect on operation and/or extending usable lifetime of the device.

### BRIEF DESCRIPTION OF THE DRAWINGS

The foregoing and other objects, features and advantages will be apparent from the following description of particular embodiments of the invention, as illustrated in the accompanying drawings in which like reference characters refer to the same parts throughout the different views.

FIG. 1 is a schematic side view of a functionalized glass-substrate device;

FIG. 2 is a simplified flow diagram of a method of manufacturing a functionalized glass-substrate device;

FIG. 3 is a simplified view of a microchannel plate with details of coated layers;

FIG. 4 is a simplified cross-sectional view of a microchannel plate showing details of coated layers.

### DETAILED DESCRIPTION

### Overview

This application discloses the use of ion barrier coatings that can be effective in preventing ionic diffusion between thin film coatings and underlying support substrates, such as glass substrates. The present description focuses on use for so-called microchannel plates (MCPs), which are planar solid-state electron multipliers consisting of a thin glass plate permeated with a large number (e.g., millions) of parallel, micron-scale pores having high length/diameter aspect ratio. One general class of embodiments employs functional layers that may be coated by atomic layer deposition (ALD), including a resistive layer and an emissive layer for generating secondary electrons in operation. In operation each pore acts independently to amplify electron signals incident on the front surface, allowing MCPs to be utilized in a wide range of imaging and detecting sensors.

MCPs may be fabricated from lead-based glass and glasses with low softening point which can incorporate a variety of ionic species such as, PbO, K₂O, and/or Na₂O among other components. High-temperature thermal processing, the use of high electric fields during operation, and chemical potentials between the ionic species and the functional layers, provide an opportunity for mobile components of the glass, including K, Na, and Pb ions for example, to diffuse to the MCP pore surfaces, where they may alter and degrade electronic properties of the MCP such as electrical resistance, secondary electron emission and electrical stability.

To reduce such issues, an ion barrier layer is used between a glass substrate and separately applied functional layers, such as conventional resistive and emissive layers used in MCPs. The ion barrier layer or coating can prevent or at least limit ion migration even at high temperatures (100-500 C) used during processing such as in the manufacture of sealed photodetectors, as well as under conditions of high electric field encountered in operation. This limiting of ion migration can preserve quality of operation and enhance life durability of the MCPs as well as the devices that they are used in, such as sealed photodetectors. It also may enable use of various glass types that might otherwise not be suitable due to their compositions. Example thin film ALD ion barrier coatings which may be effective include metal oxides such as Al₂O₃, TiO₂, Y₂O₃, ZrO₂, HfO₂, La₂O₃, and Sc₂O₃. The class of ALD ion barrier layers described herein may have broad application beyond MCPs; they may also be useful for applications such as flat panel displays and semiconducting microelectronics devices (especially 3D integrated devices), electrochromic windows, and CIGS (Cu(In,Ga)Se₂) photovoltaics, a promising candidate for flexible photovoltaics because of its outstanding efficiency and flexibility.

### Embodiments

FIG. 1 shows a functionalized device 10 having a set of layers or coatings 12 on a glass substrate 14. The layers 12 include one or more functional (FN′L) layers 16 and a barrier layer 18. The barrier layer 18 is disposed between the substrate 14 and functional layers 16 to reduce migration of ion species from the glass substrate 14 into the functional layers 16, where they can create performance and/or lifetime issues such as described above. In one embodiment, the glass substrate 14 is a microchannel plate (MCP) and the functional layers 16 include at least a resistive layer and an emissive layer, as generally known in the art. The barrier layer 18 may be of a metal oxide material, examples of which are described below.

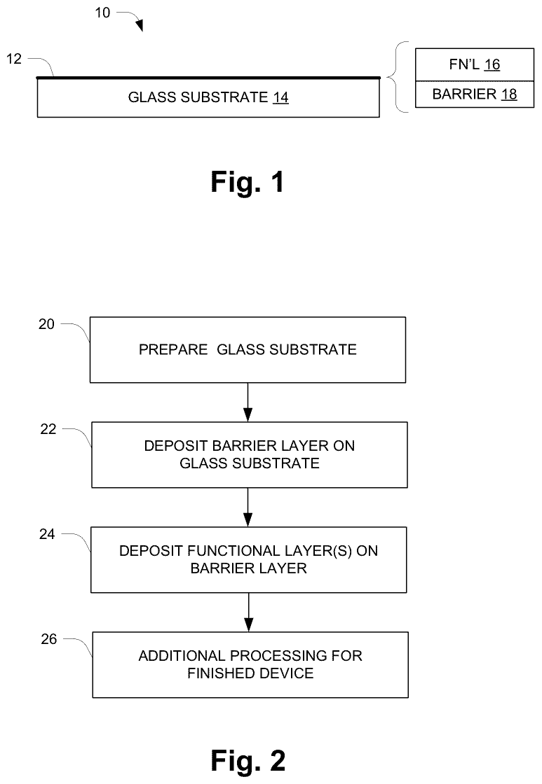

FIG. 2 is a simplified, high-level flow diagram for a process of making a functionalized device such as that of FIG. 1. At 20, a glass substrate is prepared, which may include steps of vacuum and air baking to remove moisture and organics from its surface. The glass substrate generally has a chemistry that includes one or more ionic species subject to diffusion toward the substrate surface during later processing and/or subsequent device operation, such as an alkali-containing lead glass for example. At 22, an ion barrier layer is deposited on the prepared surface of the glass substrate. The ion barrier layer is substantially of a metal oxide material that is effective to limit further diffusion of the ionic species into the separate functional layer(s) to be deposited subsequently, which have one or more functional characteristics subject to alteration by introduction of the ionic species during operation of the device. Such characteristics can include resistivity and emissivity, for example. At 24, the functional layer(s) are deposited on the ion barrier layer, and at 26 there is generally additional processing for a fully completed/finished device (e.g., thermal annealing of deposited layers, deposition of an electrical contact layer, etc.).

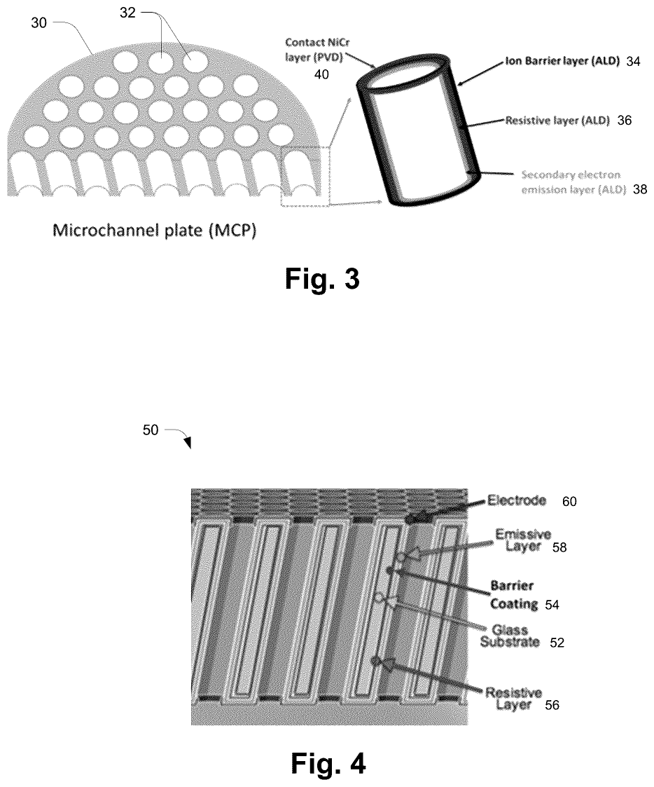

FIG. 3 shows features and details of an example application in which the finished, functionalized device is a glass-substrate microchannel plate (MCP) 30. This is an example of the generalized structure shown in FIG. 1. In this simplified depiction the pores 32 are shown with several times enlargement. The layer structure of an individual pore 32 is shown at right. It includes an ion barrier layer 34, resistive layer 36 and secondary electron emission (“emissive”) layer 38 in succession, all deposited by atomic-layer deposition (ALD) as indicated. The resistive and emissive layers 36, 38 are examples of functional layers 16 (FIG. 1). At the top is an electrical contact layer 40 formed of nickel-chromium (NiCr) and applied by physical vapor deposition (PVD) in one example.

FIG. 4 is another view of an example MCP 50 in cross section, showing the glass (substrate) 52 and the barrier coating 54, resistive layer 56, and emissive layer 58 formed on the pore walls. It also shows the electrode layer 60 formed at top. This is also a specific example of the generalized structure of FIG. 1. In some embodiments, the layers 54, 56 and 58 can have thicknesses in the range of 10-100 nm.

In the examples above, it is contemplated that the glass substrate (e.g., 14, 30, 52) may be of a variety of glass types. As noted, the barrier layer may be particularly effective with alkali-containing substrates such as lead (or lead-oxide) glass. Other glass types specifically contemplated are borosilicate glass, aluminosilicates, and soda lime glass, including in non-MCP applications such as mentioned below. In some applications, lead-oxide glass may be in the nature of a transitional technology subject to replacement by non-Pb glass compositions. However, even such non-Pb compositions may incorporate alkali, because it allows the glass to be fabricated into substrates at lower temperatures. Another class of applications is in ceramic channel multipliers with C5 borosilicate coating.

Example materials for barrier layer 18 include metal oxides such as Al₂O₃, TiO₂, Y₂O₃, ZrO₂, HfO₂, La₂O₃, and Sc₂O₃. These have varying characteristics and effectiveness as barrier layers for a variety of applications where thermally and chemically induced ionic diffusion might be a problem. In addition to thermally and chemically induced diffusion, effective barrier coatings for MCPs should also be able to withstand ionic diffusion induced by the high voltage potential and electron bombardment conditions that MCPs operate under.

Ion barrier layers as disclosed herein may be useful in other applications such as flat panel displays and semiconducting microelectronics devices (especially 3D integrated devices) where ion migration barriers are needed, as electrochromic windows, and CIGS (Cu(In,Ga)Se₂) photovoltaics, a promising candidate for flexible photovoltaics because of its outstanding efficiency and flexibility. They may also be used for coating glass vials in the pharmaceutical industry, to prevent mobile ions and other glass components from leaching and minimize the risk of their interaction with the drugs they contain, improving stability and shelf life.

The disclosed metal oxide barrier coatings may also be effective in the following applications, in which the problematic ionic species (e.g., alkali) potentially migrate to a glass or crystalline substrate from a separate layer, such as an alkali-containing photocathode layer:
a. Cherenkov Radiator, Scintillating Crystals with Alkali Metal based Photocathode Coatings
b. Bi-alkali photocathode application to Lead Tungstate Crystals

In particular, a barrier coating as disclosed herein may be used in a photodetector device which may be realized using a glass substrate such as fused silica, or alternatively a crystalline substrate such as sapphire or lead tungstate, with the barrier layer separating the glass or crystalline substrate from an alkali-containing functional photocathode layer.

While various embodiments of the invention have been particularly shown and described, it will be understood by those skilled in the art that various changes in form and details may be made therein without departing from the scope of the invention as defined by the appended claims.

What is claimed is:

1. A functionalized glass device, comprising:
a glass substrate having a chemistry including an ionic species subject to diffusion toward a surface thereof;
a functional layer supported by the glass substrate and having a functional characteristic subject to alteration by introduction of the ionic species during operation of the device; and
an ion barrier layer disposed between the surface of the glass substrate and the functional layer, the ion barrier layer being substantially of a metal oxide material effective to limit the diffusion of the ionic species into the functional layer.

2. A functionalized glass device according to claim 1, wherein the ionic species is an alkali or alkaline-earth species.

3. A functionalized glass device according to claim 2, wherein the glass substrate is formed of lead-oxide glass.

4. A functionalized glass device according to claim 1, wherein the glass substrate is formed of a material selected from borosilicate glass, aluminosilicate glass, and soda lime glass.

5. A functionalized glass device according to claim 1, wherein the metal oxide material is selected from the group consisting of Al₂O₃, TiO₂, Y₂O₃, ZrO₂, HfO₂, La₂O₃, and Sc₂O₃ or mixtures thereof.

6. A functionalized glass device according to claim 1, formed as a microchannel plate in which the glass substrate has a planar shape and contains an array of through-hole pores having sidewalls coated with the ion barrier layer and the functional layer.

7. A functionalized glass device according to claim 1, wherein the functional layer is one of a set of functional layers of the device including a resistive layer and a secondary-electron emission layer.

8. A method of making a functionalized glass device, comprising:
depositing an ion barrier layer on a surface of a glass substrate, the glass substrate having a chemistry including an ionic species subject to diffusion toward the surface, the ion barrier layer being substantially of a metal oxide material effective to limit further diffusion of the ionic species into a separate functional layer having a functional characteristic subject to alteration by introduction of the ionic species during operation of the device; and
depositing the functional layer on the ion barrier layer.

9. A method according to claim 8, wherein the ionic species is an alkali or alkaline earth species.

10. A method according to claim 9, wherein the glass substrate is formed of lead-oxide glass.

11. A method according to claim 8, wherein the glass substrate is formed of a material selected from borosilicate glass, aluminosilicate glass, and soda lime glass.

12. A method according to claim 8, wherein the metal oxide material is selected from the group consisting of Al₂O₃, TiO₂, Y₂O₃, ZrO₂, HfO₂, La₂O₃, and Sc₂O₃ or mixtures thereof.

13. A method according to claim 8, formed as a microchannel plate in which the glass substrate has a planar shape and contains an array of through-hole pores having sidewalls coated with the ion barrier layer and the functional layer.

14. A method according to claim 8, wherein the functional layer is one of a set of functional layers of the device including a resistive layer and a secondary-electron emission layer.

15. A method according to claim 8, wherein the depositing steps comprise atomic-layer deposition.

16. A method according to claim 8, further including (i) preparatory steps for preparing the glass substrate for receiving the ion barrier layer and functional layer and (ii) finishing steps for completing the functionalized glass device after the depositing steps, the preparatory steps including baking to remove moisture and organics, the finishing steps including thermal annealing of the deposited layers.

17. A photodetector device, comprising:
a glass or crystalline substrate having a functional characteristic subject to alteration by introduction of an ionic species during operation of the device;
a functional layer supported by the substrate and having a chemistry including the ionic species subject to diffusion toward a surface thereof; and
an ion barrier layer disposed between the substrate and the surface of the functional layer, the ion barrier layer being substantially of a metal oxide material effective to limit the diffusion of the ionic species into the substrate.

18. A photodetector device according to claim 17, wherein the substrate is a fused-silica window layer.

19. A photodetector device according to claim 17, wherein the substrate is a crystalline substrate of a crystalline material selected from sapphire and lead tungstate.
